(19) United States
(12) Patent Application Publication
(10) Pub. No.: US 2002/0190337 A1
(43) Pub. Date: Dec. 19, 2002

(54) Method and apparatus for the sensing of a temperature and/or the provision of heat

(75) Inventors: Andrew Alan House, Oxford (GB); Ian Edward Day, Oxford (GB)

Correspondence Address: DALLAS OFFICE OF FULBRIGHT & JAWORSKI L.L.P., 2200 ROSS AVENUE, SUITE 2800, DALLAS, TX, 75201-2784, US

(73) Assignee: Bookham Technology PLC, Oxfordshire (GB)

(21) Appl. No.: 10/141,519

(22) Filed: May 7, 2002

(30) Foreign Application Priority Data
May 10, 2001 (GB) 0111489.1

(51) Int. Cl. H01L 31/058

(52) U.S. Cl. 257/467

(57) ABSTRACT

A device 102 incorporating a sensor 106 for sensing a temperature of the device and/or a local heater 106 for the provision of heat to a minority area within the device, wherein the sensor and/or the local heater comprises at least one semiconductor element 302,804 which is fabricated as part of the device.

The present invention provides a temperature sensor and/or local heater which is fabricated as an integral part of a device. This provides the advantages of a saving of in-device package space, and allows greater versatility in sensor/local heater location.

This invention relates to the sensing of a temperature and the provision of heat. More specifically, this invention relates to a method and apparatus for sensing a temperature of, or within, a device, and/or for providing heat locally within a device.

Optical devices and analogous electrical and electronic devices are often required to be operated under very stable temperature conditions. When heating alone is used to correct the temperature of operation, the temperature of the device is usually set to be a little higher than the ambient temperature. For example, the operating temperature may be 75° C. for a device operating in an external environment which temperature ranges from 0° C. to 70° C. When a thermoelectric cooler is used, the operating temperature may be either side of ambient.

As an example, optical chips manufactured in silicon often contain elements that have strict temperature stability requirements. These requirements may be as specific as ±0.1° C. around a required temperature, for example. In order to maintain the temperature of a device within the acceptable limits therefor, accurate temperature sensing must be provided in order that the temperature regulating scheme provided to the device may function effectively.

Further, in order that a device may be retained at or around a required temperature, it is often necessary to provide a heater or heating element in order that the heat referred to above may be provided. This is especially so for optical devices which may be temperature tuned to the correct centre channel wavelength or devices the efficiency of which increase at elevated temperatures.

At the present time, the method by which temperature sensing is provided to a device which requires temperature sensing and/or temperature regulation is less than ideal. A discrete thermistor or resistive temperature device (RTD) is mounted onto the surface of the device which temperature requires sensing. Adhesion of the thermistor or RTD is achieved by a layer of conductive epoxy. In effect, the thermistor or RTD is glued to the device which temperature it is provided to sense. Additionally, a wire bond must be provided between the thermistor or RTD and an electrical contact on the device which temperature is to be sensed.

The approach is similar for the provision of heat to a device. A heat source must be applied externally to the device, i.e. on the surface thereof. A resistor may be mounted to the device by adhering it, using a layer of conductive epoxy, to a metal contact pad. Again a wirebond connection is required to complete the circuit. An alternative approach is to include a metal film resistor in the carrier (housing) of the device. This avoids the extra wirebond and adhesion steps required above.

There are various disadvantages associated with these current approaches. Firstly, referring to the sensing of temperatures, the epoxy used to adhere the thermistor/RTD to the device requiring temperature sensing provides a thermal path between the device and the temperature sensor. As such, the temperature sensed will not be a true reading, but rather a value that is offset. If the offset varies with temperature, this problem is amplified. Secondly, the size of the thermistor/RTD is problematic. This is for several reasons. If the temperature which needs sensing is at a specific or very small location, the size of the sensor may be too large and thus may provide a temperature measurement around the desired region only. This is undesirable. Additionally, thermistors/RTDs require a significant amount of space within a device package. This acts against the desire, and indeed the requirement, that device size is reduced. Again, this is a problem which needs resolving.

Secondly, referring to the provision of heat, the lack of intimate contact between the device and the heater introduces a thermal resistance in the path therebetween. This reduces the efficiency of the heater in heating the device. The same deficiencies relating to the size of RTDs/thermistors apply to resistors too.

In order to further highlight the above problems, a particular example relating to the sensing of a temperature is set forth. If a thermistor is utilised as a part of a negative feedback control loop being used to stabilise the temperature of a monitored element, problems may arise. The surface mounting of the thermistor provides a significant resistance in the path of the heat flux from the monitored element to the sensor. This can lead to a discrepancy between the thermistor temperature and the device temperature. This may cause the thermistor temperature to lag the chip temperature and may lead to a constantly oscillating device temperature. Further, the above may cause problems in devices which utilise or encompass thermal cycling.

As will be appreciated readily, there exist various problems and deficiencies with temperature sensors available for sensing temperatures in optical, electrical and electronic devices and in heaters/heating elements available for providing heat to the same. There is thus a need to provide a temperature sensor and/or a heater which addresses one or more of the above problems.

With the foregoing in mind, the present invention provides a temperature sensor and/or a local heater which is an integral part of a device which temperature requires sensing and/or regulating.

In accordance with the present invention, there is provided a device incorporating a temperature sensor for sensing a temperature of the device and/or a local heater for the provision of heat to a minority area within the device, wherein the sensor and/or local heater comprises at least one semi-conductor element which is fabricated as a part of the device.

Preferably, the device is a semiconductor device. Preferably, the device comprises at least one element manufactured from a semiconductor material. More preferably, the semiconductor is silicon (Si), gallium arsenide (GaAs), indium phosphide (InP) or indium gallium arsenide phosphide (InGaAsP).

Preferably, the semiconductor element or elements comprises one or more resistor, diode, transistor, thyristor and/or region of doping (i.e. n or p type doped region). More preferably, the semiconductor element comprises one or more PIN type diode. Still more preferably, the semiconductor element comprises one or more NIN or PIP type resistor. It may alternatively comprise one or more PIP type resistor and NIN type resistor, or one or more resistor and diode.

Preferably, the temperature sensor and/or local heater is fabricated as a part of the semiconductor device or material. More preferably, the temperature sensor and/or local heater is fabricated adjacent a region, of the device, which requires its temperature sensing and/or requires heat providing to it. Still more preferably, the temperature sensor and/or local heater is shaped so as to correspond to a region of the device, that region requiring its temperature sensing and/or requiring the provision of heat.

In a preferred embodiment, the semiconductor is fabricated by the introduction of dopant to a region of the device or an element thereof. There may be provided more than one type of dopant to specific areas within the region. In a further preferred embodiment, the semiconductor element is fabricated by ion implantation. Preferably, the device is an optical device. Still more preferably, the optical device is an optical arrayed waveguide grating, a variable optical attenuator array, a multiplexer or a demultiplexer.

In a preferred embodiment of the present invention, the local heater includes an array of heating elements configured to balance power dissipation in the minority region of the device, the minority region containing one or more power dissipative elements, the array including two or more semiconductor elements fabricated as a part of the device.

Preferably, the array of heating elements is located adjacent the minority region of the device. The minority region may further comprise an array of power dissipative elements.

Preferably the elements of the array of heating elements and of the array of power dissipative elements are arranged such that they are physically interspersed with one another. More preferably, the interspersed elements are fabricated in such a configuration in the minority region of the device.

Also in accordance with the present invention there is provided a method of manufacturing a device which requires a temperature thereof to be sensed and/or requires the provision of heat to a minority region thereof, the method comprising the steps of:

fabricating the device; and

fabricating, as a part of the device, a temperature sensor and/or local heater comprising one or more semiconductor elements.

Preferably the temperature sensor is fabricated in a specific region, of the device, in order to probe the temperature of that region. Preferably, the local heater is fabricated in a specific region of the device in order to provide heat thereto, or to dissipate power therein. More preferably, the temperature sensor and/or local heater is shaped so as to correspond to a region of the device.

Preferably, the step of fabricating the temperature sensor and/or local heater comprises introducing one or more dopants to a region, of the device, in which the temperature sensor and/or local heater is to be located. More preferably, the step of fabricating the temperature sensor and/or local heater comprises carrying out ion implantation in a region, of the device, in which the temperature sensor and/or local heater is to be located. Preferably, the device is a semiconductor device, or a device comprising at least one element manufactured from a semiconductor material. More preferably, the semiconductor/semiconductor material is silicon (Si), gallium arsenide (GaAs), indium phosphide (InP) or indium gallium arsenide phosphide (InGaAsP).

Preferably, the semiconductor element or elements comprises one or more resistor, diode, transistor, and/or thyristor. Still more preferably, the semiconductor element(s) comprise one or more PIN type diode and/or NIN type resistor.

Also in accordance with the present invention there is provided a method of balancing the power dissipation of a device containing one or more elements having a thermal output, the method comprising:

providing an array of integrated local heating elements in the device;

decreasing the power dissipation of the elements having a thermal output; and

increasing the power dissipation of the array.

Preferably, the array is provided adjacent the elements having a thermal output. Preferably, a region of the device in which the element or elements having a thermal output is/are located is a minority region of the device.

Alternatively, a region of the device may contain an array of the elements having a thermal output and the elements of the array of local heating elements interspersed therewith.

In a specific realisation of this embodiment, the device is an optical device comprising one or more variable optical attenuators, and the step of decreasing the power dissipation comprises decreasing the attenuation setting of the variable optical attenuator.

Various specific embodiments of the present invention are now described, by way of example only, with reference to the accompanying drawings, in which:

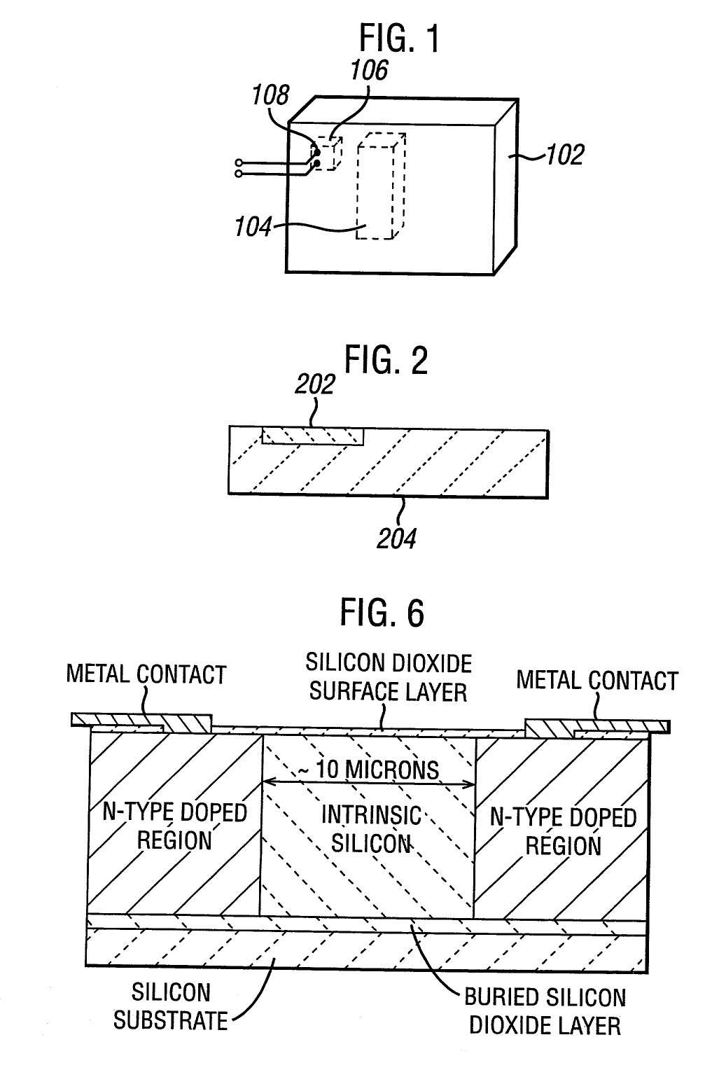

FIG. 1 is diagram illustrating a device according to the present invention;

FIG. 2 is a more detailed illustration of the device of FIG. 1;

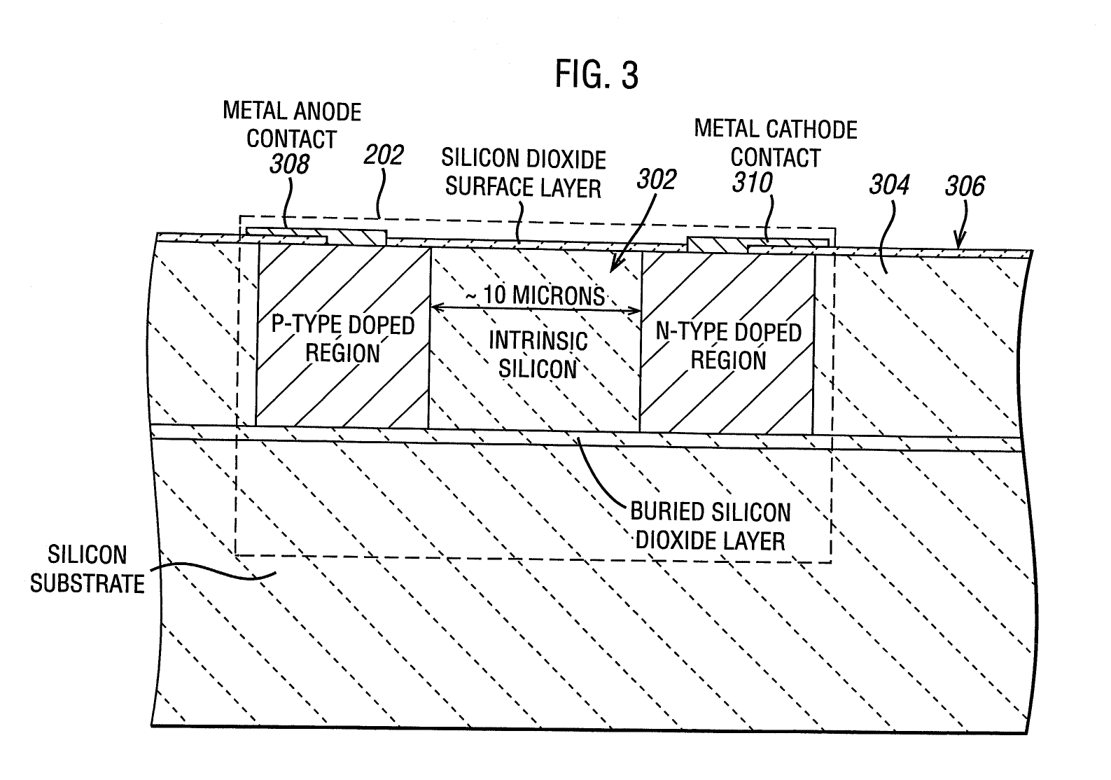

FIG. 3 is an illustration of a specific realisation of the present invention in which the temperature sensor is provided by a PIN diode;

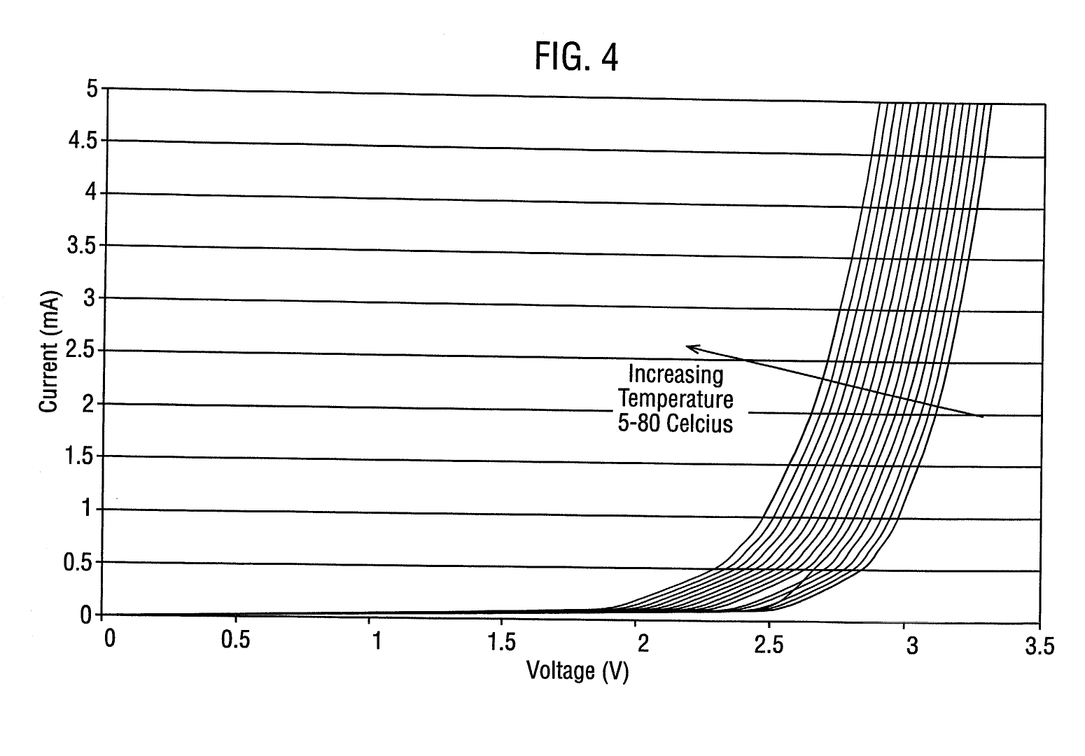

FIG. 4 is a graphical representation of the current-voltage characteristics of the PIN diode of FIG. 3, plotted using real data;

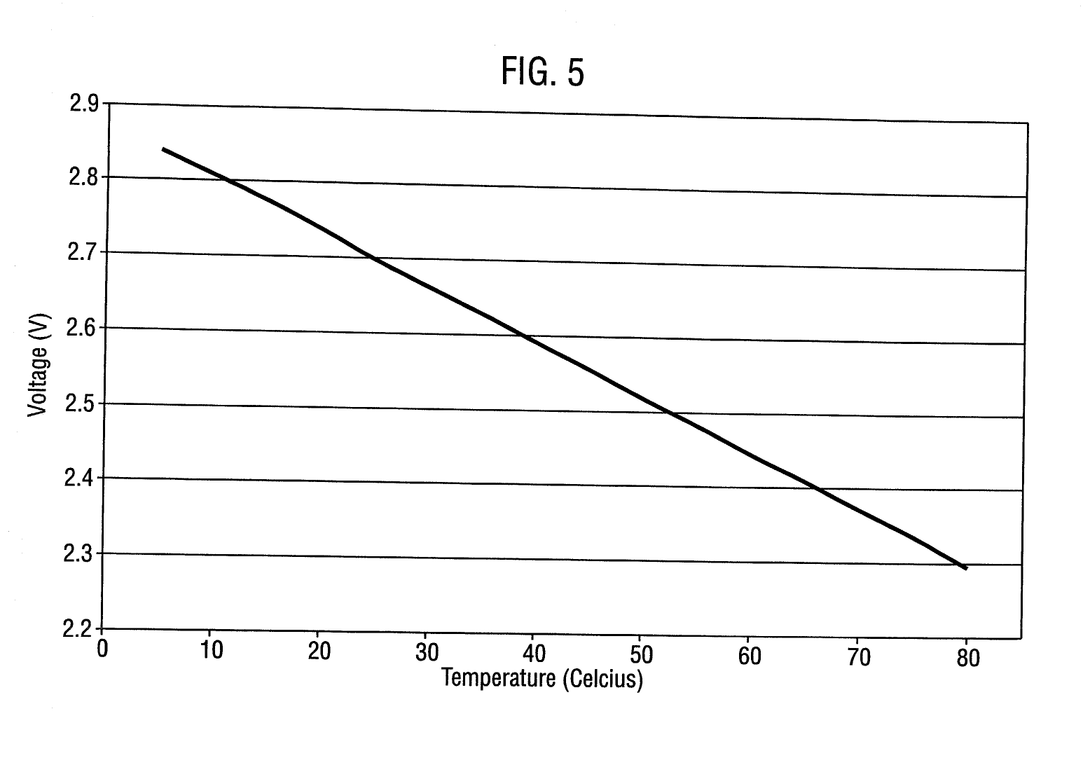

FIG. 5 is a graphical representation of the relationship between voltage and ambient temperature at a set current for the diode of FIG. 3, plotted using real data;

FIG. 6 is a diagram of a resistor which may be used to provide the temperature sensor of the present invention;

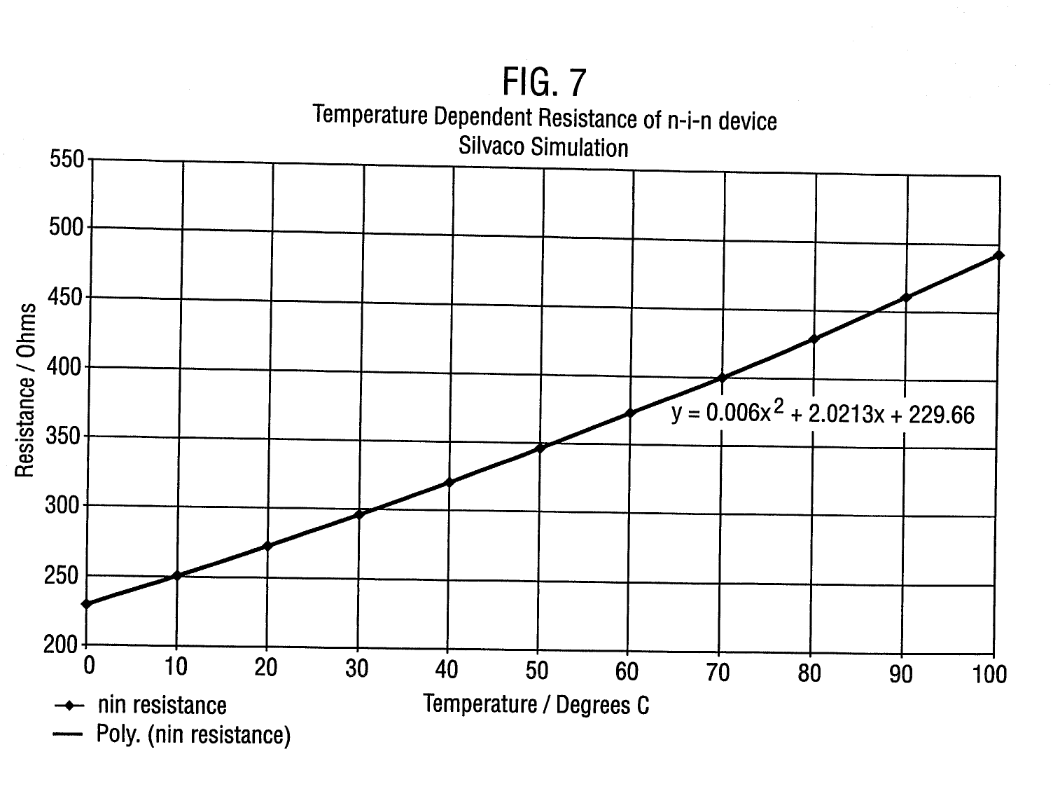

FIG. 7 is a graphical representation of the relationship, simulated, between resistance and temperature for the resistor of FIG. 6;

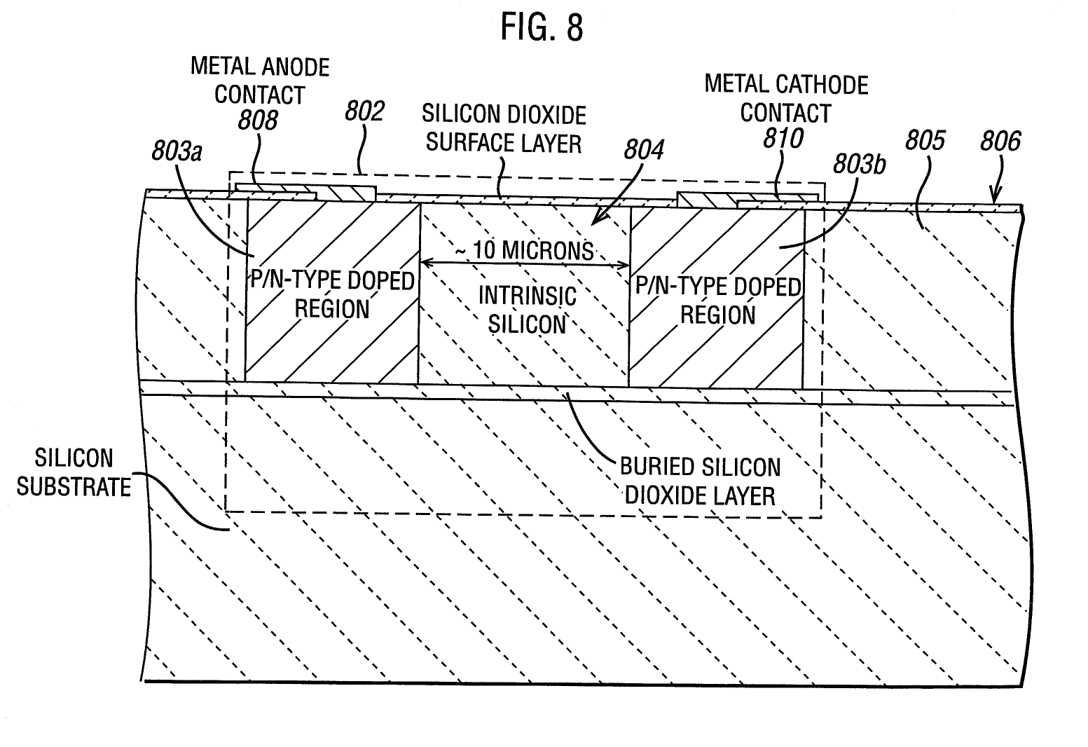

FIG. 8 is an illustration of a specific realisation of an alternative embodiment of the present invention; and

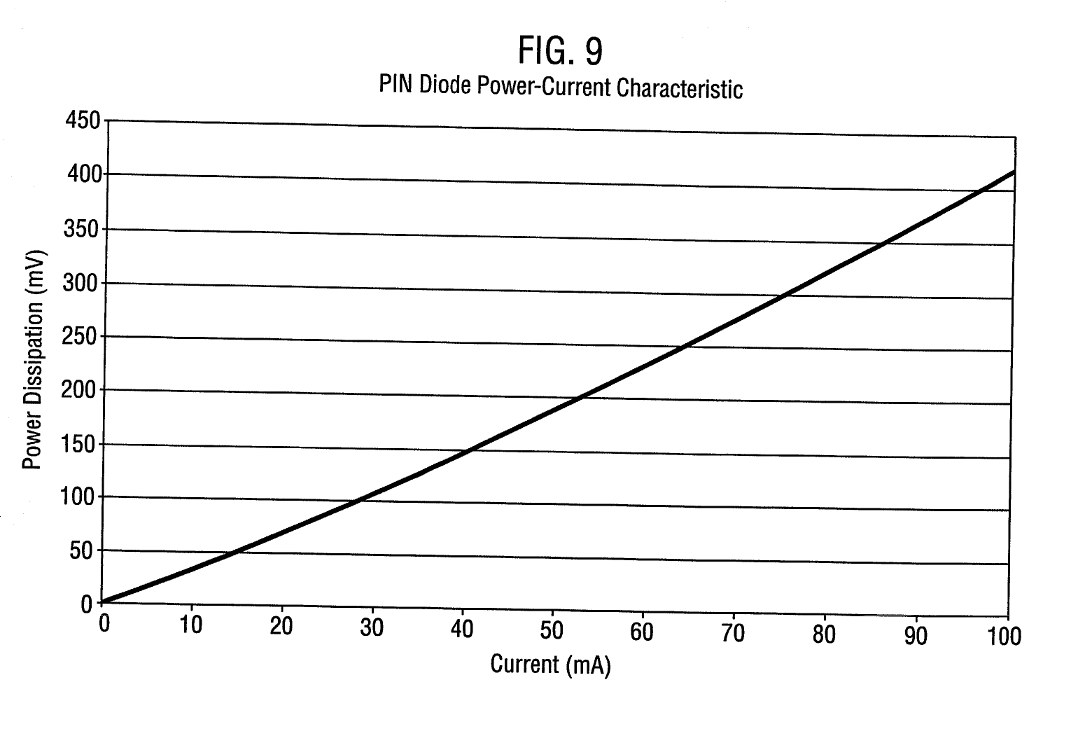

FIG. 9 is a graphical representation of the power dissipation with current of an embodiment of FIG. 8, plotted using real data.

As may be seen in FIG. 1, the present invention comprises a number of elements. It is these elements, and their interconnection and operation, that provide the advantages which distinguish this invention from the prior art.

In the very basic form of FIG. 1, the invention is utilised in and/or comprises a device 102 which requires that a temperature thereof is sensed or requires that heat be provided to it. This device may be an optical device, such as an optical device constructed in a silicon substrate for example, or it may be an analogous electrical or electronic device. However, irrespective of the purpose for which the device is intended, it is a device which requires that either its overall temperature, the temperature of an element 104 thereof, or the temperature of a region or area within the device 102 is sensed, for some purpose, or is contributed to by some form of heater or the like. There is also present a temperature sensor/heater 106. As may be appreciated from FIG. 1, the temperature sensor/heater is an integral part of the device. This will be discussed in greater detail below. The temperature sensor/heater also comprises electrical contacts to enable it to be connected to a temperature control or regulation circuit, thereby enabling it to be utilised. Such contacts may be in the form of electrical pads 108 fabricated onto the sensor/heater element within the device.

FIG. 2 depicts a preferred embodiment of a temperature sensor/heater according to the present invention. As is shown, the temperature sensor/heater 202 is fabricated as an integral part of the device 204. A specific example of this embodiment is a device made from or having a substrate constructed from silicon. In this case, the temperature sensor/heater 202 is formed as a part of the silicon element or substrate. This provides a truly integrated sensor or heater. Of course, this invention is applicable to materials other than silicon (Si), it may be used in devices made from or having a substrate of gallium arsenide (GaAs), indium phosphide (InP) or indium gallium arsenide phosphide (InGaAsP). Also the device may have within it one or more integrated temperature sensors and/or heaters, for example.

A major advantage of the above approach is that the sensor or heater is fabricated in the same piece of material as the structure of the device. Such an arrangement ensures that the element is in the most intimate physical contact with the structure that can be achieved.

Other advantages of this approach are as follows. In a situation wherein the device which requires its temperature monitoring and/or requires the provision of heat is a chip, such as an optical chip or an integrated circuit formed in a silicon chip, for example, the manufacture of the device and temperature sensing element and/or heating element is simplified. This is because an element, such as that illustrated in FIG. 2, may easily be produced/fabricated at the same time as the rest of the chip. No new process steps are required. Another advantage lies in the size of the integrated sensor. For example, integrated temperature sensors may be fabricated to be much smaller than thermistors. A thermistor may have a footprint in the region of 0.5 mm², whereas an integrated temperature sensor may be manufactured to have the equivalent of a footprint of 10⁴ μm² or less. Similar dimensions are applicable to integrated heaters also.

This provides a further advantage. The provision of such small elements enables the temperature of smaller local regions within a device to be probed. It also allows the local provision of heat within a device. This is advantageous, because larger surface mounted thermistors or heaters, for example, can only read an average temperature for an area in the millimeter scale or provide heat across such an area, respectively. Clearly, this is undesirable in both a situation where an accurate temperature reading for a small region of a device is required, and where the temperature of a small region of a device is required to be increased or retained at a specific value.

A first specific realisation of a temperature sensor according to the present invention is now described with reference to FIG. 3. As is shown, the integrated temperature sensor 202 takes the form of a PIN diode 302. Similar temperature sensors may be realised based upon alternative semiconductor devices. For example, thyristors, transistors, simple resistors and/or circuits comprising one or more such semiconductor devices may be utilised.

However, whilst the examples set forth below exhibit equivalent sensitivity, it is believed that the operating principle of p-n junction based devices is more likely to yield a sensitive temperature sensor than a simple integrated resistor, because the physics of carrier injection occurring at the junction has an intrinsically high temperature dependence. This carrier injection process does not occur in a simple NIN/PIP resistor. This device relies instead upon electron drift as its carrier mechanism.

The PIN diode shown in FIG. 3 is one of the simplest of the p-n junction and other semiconductor devices which may be utilised as an integrated temperature sensor. Another such device, an NIN resistor, will be described later with reference to FIG. 6.

Referring now to the PIN diode, 302, it is clear that it has been fabricated within the material 304 of the device 306 which temperature it is provided to sense. In order that the PIN diode 302 may be utilised as a temperature sensor, it is provided with a small current (approximately 0.5 mA) by a constant current source. This current serves to forward bias the diode 302.

The voltage across the diode junction decreases with increasing temperature, at a set value of current. Hence, the voltage generated across the diode may be measured and the temperature dependent characteristics of the diode 302, along with the voltage measured across the diode 302 via anode and cathode contacts 308, 310, serve to provide a temperature value for the location of the diode 302. Therefore, it is the temperature dependence of the diode 302 that allows it to act as a temperature sensor. Similarly, it is the nature of the diode and its construction which allows it to be integrated within suitable devices.

A typical PIN diode 302, such as that shown in FIG. 3, exhibits a turn on voltage of approximately 0.7 V. The sensitivity of the temperature measurement that may be achieved using such devices can be increased by utilising more than one p-n junction device or element. Accordingly, a number of PIN diodes may be connected together. An example of this is the connection of four PIN diodes, in series, to provide greater accuracy. The connection of n such diodes in series will increase the voltage drop across the combined sensor to 0.7V×n. It is this increase in voltage drop which increases the precision of the sensor.

The operation of the PIN diode 302 of FIG. 3 as a temperature sensor is now described with reference to FIG. 4. FIG. 4 shows a number of current-voltage (IV) characteristics recorded using a series combination of four PIN diodes. As may be seen, the turn on voltage of the four diode series combination is approximately 2.8V. This follows the relationship (0.7V×n) set out above. The characteristics were measured at 5° C. intervals across the range 5 to 80° C. As will be appreciated, FIG. 4 shows that, at a constant set current, the voltage across the temperature sensor falls with increasing temperature.

Clearly, the diode IV characteristics are non linear, especially in the region representing the “turning on” of the diodes. However, as the operating voltage is increased to be above the turn on voltage of the diodes, the characteristics become more linear. Ideally, a temperature sensor should have a linear variation with temperature, thus it might be expected that a PIN diode-based sensor would need to be biased such that its operating point was in the linear portion of the IV-characteristic. However, the inventors found that it is important that the operating point is not set at too high a current value. If this happens, there may be a significant level of ohmic heating, caused by the current, which will alter the local temperature at the sensor and result in error in the temperature reading. Additionally, the generation of such heat could have adverse effects on nearby circuitry and/or device elements which could have a knock on effect in, for example, devices which require control of their temperature within narrow bands. With this in mind, it was found that a current of approximately 0.5 mA was suited for this application.

The variation of the voltage across the sensor with ambient temperature was recorded and the relationship is set forth in FIG. 5. As is clear, the variation is substantially linear and this leads to a reliable temperature sensor, after the calibration thereof. However, it should be noted that, as will be explained further below, calibration against an absolute temperature scale is not necessarily required.

As mentioned previously, the constant current that is driven through the sensor must be sufficiently small that it does not provide any substantial heating effect within the sensor due to ohmic heat dissipation. This point has been investigated using thermal modelling simulations.

It was found that the ohmic power dissipation within such a temperature sensor is not sufficient to introduce a significant measurement error.

The sensor modelled was 11 mm long, 10 μm wide and 2 μm in depth. It was assumed that the ohmic dissipation in the sensor was 1.5 mW (i.e. the same as that of a sensor that drops 3V when a 0.5 mA current is supplied to it, cf. FIG. 4). The results of this modelling work are shown in Table 1 below.

TABLE 1

| Heat | | T_{L} | T_{M} | T_{R} |
|---|---|---|---|---|
| transfer | | (Sensor | (Sensor | (Sensor |
| coefficient | Resistance | Left-End | Mid-Point | Right-End |
| W/(m²K) | K/W | Temperature) | Temperature) | Temperature) |
| 1.00 | 274 | 0.205 | 0.207 | 0.202 |
| 10 | 27.4 | 0.029 | 0.030 | 0.026 |
| 50 | 5.49 | 0.011 | 0.013 | 0.009 |

The values of T_{L}, T_{M} and T_{R} are the temperature increases, above that of the ambient environment, which occur in the sensor due to ohmic heating effects. The resistance values in the second column are a measurement of the thermal conductivity of the environment that the sensor is placed in (i.e. how well thermally insulated it is). These values were chosen to be representative of certain typical situations. The 274 K/W case corresponds to free convection with no heat sink, the 27.4 K/V value is representative of a case of forced convection with a small air gap in a chip package and the 5.49 case is representative of convection with a high efficiency heatsink. Thus the whole likely operating temperature range of the sensor is covered by Table 1.

It is clear that the error values of Table 1 are small enough to allow temperatures to be measured to 0.1 ° C. of accuracy.

This is of particular importance in the area of optical chips and devices and other analogous electrical and electronic chips and devices, especially those manufactured in silicon. Such chips, as has already been mentioned, may need to be set to within approximately ±1° C. of a desired or operating temperature.

Further, such chips/devices, e.g. optical arrayed waveguide gratings (AWGs) used in mutliplexers and dimultiplexers for use in dense wavelength division multiplexing (DWDM), may need to be regulated to within approximately ±0.1 ° C. of a desired or operating temperature.

Hence, in situations where regulation to within ±0.1° C. of a set-point is required, but where the absolute value of the set-point is not important, the sensor set forth above will be effective, because the effects of ohmic heating are likely to result in a constant temperature offset. The errors shown in Table 1 above are therefore of a systematic nature and would have little effect on the temperature stability of such a device.

A second specific realisation of the present invention is now described with reference to FIG. 6. This embodiment is identical to that described first, with the exception that, in the place of the PIN diode described, there is utilised an NIN resistor. This NIN resistor, as shown in FIG. 6, is identical to a current deep etch diode structure. However, in the place of the usual p-type diffusion, there is provided n-type diffusion. Additionally, the background doping of the diode may be set to be n-type.

Again, at each set-temperature, this time between 0 and 100° C., an IV characteristic was generated by device simulation and, from this, a resistance was determined. This is shown, plotted against temperature, in FIG. 7. It is clear that this device also will provide a good temperature sensor base, as the points in the dependency chart are joined using a second order polynomial fit.

Specific realisations of an integrated heater according to the present invention are now described with reference to FIG. 8. As may be seen, the integrated heater 802 may take the form of a PIP or NIN resistor, or a PIN diode. FIG. 8 illustrates doped regions 803a, 803b of the heater 802 as both being p type (i.e. PIP resistor), both being n type (i.e. NIN resistor) or one being p type and the other being n type (i.e. PIN diode). The semiconductor element, be it resistor or diode, is assigned the reference numeral 804.

It is clear that the semiconductor element 804 has been fabricated within a material 805 of a device 806 to which it is to provide heat. Further, similarly to the resistors and diodes set forth above for use as temperature sensors, the element 804 includes metal anode and cathode contacts 808, 810 to enable the provision of current thereto.

It will be appreciated by the reader that the semiconductor elements which serve as integrated temperature sensors and integrated heaters correspond to one another. As such, the description thereof applies equally to their utilisation for either purpose, to the extent practicable.

Each of the three possible variants set forth above has it's own advantage. As such, the choice of the exact combination of p and n type doping within an integrated heater depends upon the particular application in which it is to be utilised. The use of a PIN diode configuration is particularly appropriate in applications where a heater is to be used to balance the thermal output from similar diode structures. An example of this application is the use of integrated heaters constructed in the form of PIN diodes to balance the thermal output from variable optical attenuators in an optical device. In this example, small arrays of integrated heaters are placed next to an array of variable optical attenuators such that they allow constant in device power dissipation to take place. As the attenuation setting of the variable optical attenuator is decreased (which results in less power dissipation by the attenuator) the power supplied to the array of integrated heating elements is increased. This serves to maintain the overall power dissipation at a constant level. The power dissipation with current, recorded for a series combination of four PIN diodes, is shown in FIG. 9. Further, by making the heating elements electrically identical to the variable optical attenuator diode structure, solutions are possible whereby excess current from the attenuator drive circuit (which results from the attenuation of the attenuator being reduced) is diverted to the heater elements. Further, integrated heater elements may be located in the spaces between the attenuators in the array of variable optical attenuators such that the electrical power dissipation still occurs in the same locality of the chip.

Appropriate control circuitry is required, in this last case, in order to maintain the combination of integrated heating element array and variable optical attenuator array at a constant level of electrical power dissipation. Such a control circuit may be fairly simple. A simple single transistor control circuit or a resistor diode network may serve. It is therefore feasible that the control circuitry may also be fabricated in the device, in the form of additional doped elements, or within on-device metal tracking.

The configuration of an integrated heater according to the present invention may be more elaborate than the basic form shown in FIG. 8. Particularly, PIN type devices may be concatenated in series so as to yield an appropriate turn on voltage for the heater elements. As already stated in the description relating to integrated sensors, the turn on voltage of such diodes is typically 0.7×n Volts where n is the number of diodes placed in series. This may be done so that the integrated heater acts correctly in the situation set forth in the above example, or may simply be a convenient configuration for a particular electrical drive circuit. The feature of turn on voltage may also be utilised in a situation where a control voltage is used to define when the heater turns on. The number of devices connected in series may therefore be determined such that the integrated heating elements will turn on at or around a desired value of control voltage.

The use of PIP/NIN resistors as integrated heaters has its own set of advantages. Such resistors are appropriate for use in devices that only require a single polarity of dopant. Significantly, in such a situation, the use of such resistors provides the advantage of saving an extra doping process step during the device manufacture, when compared with the manufacture of integrated heating elements in the PIN diode configuration. Such resistors also provide the advantage of providing a much lower free carrier density than that of a PIN diode configuration integrated heater. This results in resistor configuration integrated heaters being highly unlikely, and less likely than PIN diode configuration integrated heaters, to introduce electrical crosstalk due to carriers inadvertently escaping, into nearby optical waveguides for example. This advantage is a result of the main conduction mechanism in PIP/NIN resistors being carrier drift, rather than the carrier diffusion that takes place in PIN diodes.

As will be appreciated, because the sensor and the heater of the present invention are fabricated as an integral part of the device in which they are to be utilised, their shapes have great flexibility. Such elements may be run around tight bends or even right angles. Such a feature is of use in the situations where it is desired or necessary to monitor a temperature near or in a chip corner or to provide heat to, or dissipate power in, a minority or local region within a device, for example. A further advantage of the above approach is that it allows the simplification of device test and manufacturing by circumventing the need for the addition of discrete elements to chips. It also allows elements, be they sensors or heaters, to have improved thermal contact with the chip and to probe or heat chip regions at a finer level. This is useful today, but is likely to become increasingly important as chip size is reduced in the future. It may be the case that future AWGs or other optical elements, for example, become so small that a large discrete thermistor or resistor epoxied onto the chip surface is incapable of doing any better than probing an average temperature on a chip or heating the entire chip (or a large portion thereof), respectively. In this case, integrated elements of the types described above will be essential in measuring, heating and providing compensation schemes to cope with local temperature gradients between on-chip elements e.g. between a variable optical attenuator (VOA) array and an AWG on future, miniature multiplexer (i.e. miniature variable optical attenuator and multiplexer (MUX-VOA)) chips. However, where desired, the sensor of the present invention may measure a temperature averaged over an area. In this case, the sensor may be large, relative to a device which temperature is to be measured, and may take any shape.

In the case of integrated heaters, the intimate contact which is enjoyed with the device to be heated is particularly advantageous. This is because it enables closer control of the temperature of the device, due to the removal of thermal resistance in the adjoining path, and also reduces the amount of heat wasted by dissipation in the surrounding environment. Additionally, as stated above for temperature sensors, lag time in thermal control circuits is also reduced, which is advantageous in devices utilising thermal cycling, for example.

A significant advantage of the integrated heaters of the present invention resides in the size of heating element achievable. As will be appreciated, the integrated heaters disclosed herein may be made to be much smaller than conventional heater elements, such as resistors adhered to a device, and so may be utilised in applications which, to date, heaters have not been able to be utilised in. Such applications are those in which local heating, i.e. heating of a very small or minority area, within an optical chip is required, rather than the heating of the whole chip or a large portion thereof. This new ability also leads to the advantageous use of the integrated heaters of the present invention in balancing local power dissipation in a device, specifically an optical device.

Referring briefly to the actual fabrication procedure of a temperature sensor element or heating element of the present invention, as has already been alluded to, the element is fabricated during the fabrication of the device in which it is intended to serve. For example, in the manufacture of an optical AWG in silicon, a PIN diode is fabricated at the correct location in the silicon during the fabrication of the optical AWG. In such a case, where it is known that the chip concerned is stress sensitive, it is not possible to utilise high temperatures (which induce stress) during the process of fabricating the PIN diode, i.e. the introduction of dopant to the silicon where such is not already present (i.e. MUX-VOA). This is because, as the device is stress sensitive to high temperature process steps, low temperatures are required to avoid subjecting the device to undue stress, and thus damaging it. The problem that is then faced is how to introduce dopant(s) during a process which produces good quality waveguides, for example. This is achieved, in the present invention, using the well known process of ion implantation. The fabrication of such elements in an optical device, manufactured in silicon, for example, utilises only the steps necessary to fabricate that device. The process therefore involves no added overhead in terms of cost, time or complexity.

It will be appreciated that, whilst this invention has been described as relevant to silicon devices, it also applies to other materials in which dopants can be implanted in order to create p-n type junctions and other suitable semiconductor elements. Additionally, whilst this invention has been described as pertaining to a specific PIN diode and NIN resistor, the skilled reader will appreciate that it is also applicable to other resistors, transistors, thyristors and diodes, and any other p-n junction type device, also to circuits and combinations thereof.

It will be appreciated that this invention has been described above by way of example only, and that modifications of detail may be made within the scope of the invention.

1. A device incorporating a temperature sensor for sensing a temperature of the device and/or a local heater for the provision of localised heat to a minority area within the device, wherein the sensor and/or local heater comprises at least one semiconductor element which is fabricated as a part of the device.

2. A device as claimed in claim 1, wherein the device is a semiconductor device or comprises at least one element manufactured from a semiconductor material.

3. A device as claimed in claim 2, wherein the semiconductor is silicon (Si), gallium arsenide (GaAs), indium phosphide (InP) or indium gallium arsenide phosphide (InGaAsP).

4. A device as claimed in claim 1, wherein the semiconductor elements(s) comprises one or more resistor, diode, transistor and/or thyristor.

5. A device as claimed in claim 4, wherein the semiconductor element(s) comprises one or more PIN type diode.

6. A device as claimed in claim 4, wherein the semiconductor element(s) comprises one or more NIN type resistor.

7. A device as claimed in claim 2, wherein the temperature sensor and/or local heater is fabricated as a part of the semiconductor device or material.

8. A device as claimed in claim 1, wherein the temperature sensor and/or local heater is fabricated adjacent a region, of the device, which requires its temperature sensing and/or heat providing to it.

9. A device as claimed in claim 1, wherein the temperature sensor and/or local heater is shaped so as to correspond to a region, of the device, which requires its temperature sensing and/or the provision of heat.

10. A device as claimed in any of claims 7, wherein the temperature sensor and/or local heater is fabricated by the introduction of dopant to a region of the device or an element thereof.

11. A device as claimed in claim 7, wherein the temperature sensor and/or local heater is fabricated utilising ion implantation.

12. A device as claimed in claim 1, wherein the local heater includes an array of heating elements configured to balance power dissipation in a minority region of the device, the minority region containing one or more power dissipative elements, the array including two or more semiconductor elements fabricated as a part of the device.

13. A device as claimed in claim 12, wherein the array of heating elements is located adjacent the minority region of the device.

14. A device as claimed in claim 12 wherein the minority region contains an array of power dissipative elements.

15. A device as claimed in claim 14, wherein the elements of the array of heating elements and of the array of power dissipative elements are arranged such that they are physically interspersed with one another.

16. A device as claimed in claim 15, wherein the interspersed elements are fabricated in such a configuration in the minority region of the device.

17. A method of manufacturing a device which requires a temperature thereof to be sensed and/or requires the provision of heat to a minority region thereof, comprising the steps of:
fabricating the device; and
fabricating as a part of the device, a temperature sensor and/or local heater comprising one or more semiconductor elements.

18. A method as claimed in claim 17, wherein the temperature sensor is fabricated in a specific region of the device in order to probe the temperature of that region.

19. A method as claimed in claim 17, wherein the local heater is fabricated in a specific region of the device in order to provide heat thereto, or to dissipate power therein.

20. A method as claimed in claim 17, wherein the temperature sensor and/or local heater is shaped so as to correspond to a region of the device.

21. A method as claimed in claim 17, wherein the device is a semiconductor device, or a device comprising at least one element manufactured from a semiconductor material.

22. A method as claimed in claim 21, wherein the semiconductor/semiconductor material is silicon (Si), gallium arsenide (GaAs), indium phosphide (InP) or indium gallium arsenide phosphide (InGaAsP).

23. A method as claimed in claim 21, wherein the step of fabricating the temperature sensor/local heater comprises introducing one or more dopants to a region of the device in which the temperature sensor/local heater is to be located.

24. A method as claimed in claim 21, wherein the step of fabricating the temperature sensor and/or local heater comprises carrying out ion implantation in a region, of the device, in which the temperature sensor and/or local heater is to be located.

25. A method as claimed in claim 17, wherein the semiconductor element(s) comprises one or more resistor, diode, transistor and/or thyristor.

26. A method as claimed in claim 25, wherein the semiconductor element comprises one or more PIN type diode and/or NIN or PIP type resistor.

27. A method of balancing the power dissipation of a device containing one or more elements having a thermal output, the method comprising:
providing an array of integrated local heating elements:
decreasing the power dissipation of the elements having a thermal output; and
increasing the power dissipation of the array.

28. A method as claimed in claim 27, wherein the array is provided adjacent the elements having a thermal output.

29. A method as claimed in claim 27, wherein the element having a thermal output is located in a specific region of the device.

30. A method as claimed in claim 29, wherein the region is a minority region of the device.

31. A method as claimed in 27, wherein a region of the device contains an array of the elements having a thermal output and the elements of the array of local heating elements is interspersed therewith.

32. A method as claimed in claim 27, wherein the device is an optical device comprising one or more variable optical attenuators, the step of decreasing the power dissipation comprising decreasing the attenuation setting of the variable optical attenuator.

33. A device as claimed in claim 1, wherein the device is an optical device.

34. A device as claimed in claim 32, wherein the optical device is an optical arrayed waveguide grating (AWG), a variable optical attenuator array, a multiplexer or a demultiplexer.
